(19) United States
(12) Patent Application Publication
(10) Pub. No.: US 2014/0131811 A1
(43) Pub. Date: May 15, 2014

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Masumi SAITOH, Yokohama-shi (JP); Kensuke OTA, Fujisawa-Shi (JP); Toshinori NUMATA, Kamakura-Shi (JP); Chika TANAKA, Yokohama-shi (JP); Shinichi YASUDA, Tokyo (JP); Kosuke TATSUMURA, Kawasaki-Shi (JP); Koichiro ZAITSU, Kawasaki-Shi (JP)

(73) Assignee: KABUSHIKI KAISHA TOSHIBA, Tokyo (JP)

(21) Appl. No.: 14/072,948

(22) Filed: Nov. 6, 2013

(30) Foreign Application Priority Data
Nov. 9, 2012 (JP) 2012-247355

(51) Int. Cl. H01L 27/11; H01L 27/12

(52) U.S. Cl. CPC H01L 27/1108; H01L 27/1211
USPC 257/392; 438/276

(57) ABSTRACT

A semiconductor device of an embodiment includes: a first transistor having a first source region and a first drain region arranged in a first protruded semiconductor region, a first channel region having a first corner portion in its upper portion in a section perpendicular to a first direction, the first corner portion having a first radius of curvature; a second transistor having a second source region and a second drain region arranged in a second protruded semiconductor region, and a second channel region having a second corner portion in its upper portion in a section that is perpendicular to a second direction, the second corner portion having a second radius of curvature greater than the first radius of curvature.

### CROSS REFERENCE TO RELATED APPLICATIONS

This application is based upon and claims the benefit of priority from prior Japanese Patent Application No. 2012-247355 filed on Nov. 9, 2012 in Japan, the entire contents of which are incorporated herein by reference.

### FIELD

Embodiments described herein relate generally to a semiconductor device and a method of manufacturing the same.

### BACKGROUND

A programmable switch is a circuit that determines the logical operation function of a switch unit in accordance with information written in a memory unit after the manufacturing. A field programmable gate array (FPGA) is especially known as a programmable switch capable of rewriting logical functions repeatedly.

The memory unit of the FPGA includes a static random access memory (SRAM), which is a volatile memory, or a flash memory, which is a nonvolatile memory. The FPGA with flash memory is more preferable since it does not require saving information stored in its flash memory to another memory when the power is turned off.

Conventional FPGAs using flash memories have a structure in which a floating gate electrode of polycrystalline silicon or a charge storage layer such as a silicon nitride film is formed on the gate insulating film of a memory transistor, which is a flash memory, However, besides the memory transistor, the FPGA also includes a transistor called “pass transistor” or “switch transistor,” which does not require a memory function. The gate of the transistor that does not require a memory function does not include a charge storage layer. Accordingly, in manufacturing an FPGA, a memory embedding process is required to separately form the gate stack structures of a memory unit and a non-memory unit, which leads to a problem of high processing costs, Furthermore, since the effective gate insulating film thickness of a flash memory is as thick as 10 nm or more, a voltage as high as 10 V or more is required for the writing to the flash memory, which leads to a problem of power consumption.

### BRIEF DESCRIPTION OF THE DRAWINGS

FIG. 1 is a top view of a semiconductor device according to a first embodiment.

FIGS. 2(a) to 2(c) are cross-sectional views in the gate width direction of the semiconductor device according to the first embodiment,

FIG. 3 is a cross-sectional view in the gate length direction of the semiconductor device according to the first embodiment.

FIG. 4 is an equivalent circuit diagram of the semiconductor device according to the first embodiment.

FIG. 5(a) is a drawing showing a perspective view of the transistor used in a hot-carrier injection test.

FIG. 5(b) is a drawing showing a result of the measurement of the dependence of threshold voltage shifts caused by the hot-carrier injection on the write time.

FIG. 6 is a drawing showing a result of the measurement of the dependence of NBTI-determined lifetime on the stress voltage.

FIGS. 7(a) and 7(b) are a top view and a cross-sectional view for explaining the first example of a method of manufacturing the semiconductor device according to the first embodiment,

FIGS. 8(a) and 8(b) are cross-sectional views for explaining the first example of the method of manufacturing the semiconductor device according to the first embodiment.

FIG. 9 is a cross-sectional view for explaining the first example of the method of manufacturing the semiconductor device according to the first embodiment.

FIG. 10 is a plan view for explaining the first example of the method of manufacturing the semiconductor device according to the first embodiment.

FIGS. 11(a) to 11(c) are cross-sectional views for explaining the first example of the method of manufacturing the semiconductor device according to the first embodiment.

FIGS. 12(a) and 12(b) each are a TEM photograph after hydrogen annealing of a section of a silicon nanowire to which boron or phosphorus is injected.

FIGS. 13(a) to 13(c) are cross-sectional views for explaining a first example of the method of manufacturing the semiconductor device according to the first embodiment.

FIG. 14 is a plan view for explaining a second example of the method of manufacturing the semiconductor device according to the first embodiment.

FIGS. 15(a) to 15(c) are cross-sectional view for explaining the second example of the method of manufacturing the semiconductor device according to the first embodiment.

FIGS. 16(a) to 16(c) are cross-sectional views for explaining the second example of the method of manufacturing the semiconductor device according to the first embodiment.

FIG. 17 is a top view of a semiconductor device according to a second embodiment.

FIGS. 18(a) to 18(c) are cross-sectional views in the gate width direction of the semiconductor device according to the second embodiment.

FIG. 19 is a cross-sectional view in the gate length direction of the semiconductor device according to the second embodiment.

FIG. 20 is a plan view for explaining a method of manufacturing the semiconductor device according to the second embodiment.

FIGS. 21(a) to 21(c) are cross-sectional views for explaining the method of manufacturing the semiconductor device according to the second embodiment.

FIG. 22 is a block diagram showing a semiconductor device according to a third embodiment.

FIG. 23 is a circuit diagram showing an SRAM circuit according to the third embodiment.

FIGS. 24(a) and 24(b) are cross-sectional views in the gate width direction of transistors constituting the semiconductor device according to the third embodiment.

FIG. 25 is a drawing for explaining a method of making nonvolatile the SRAM circuit according to the third embodiment.

FIGS. 26(a) and 26(b) are cross-sectional views in the gate width direction of transistors constituting a semiconductor device according to a fourth embodiment.

FIGS. 27(a) and 27(b) are cross-sectional views in the gate width direction of transistors constituting a semiconductor device according to a fifth embodiment.

### DETAILED DESCRIPTION

A semiconductor device according to an embodiment includes: a first protruded semiconductor region extending in a first direction and having a first top surface and first side surfaces that are different from the first top surface and extend along the first direction, a second protruded semiconductor region extending in a second direction and having a second top surface and second side surfaces that are different from the second top surface and extend along the second direction, and a third protruded semiconductor region extending in a third direction and having a third top surface and third side surfaces that are different from the third top surface and extend along the third direction, the first protruded semiconductor region, the second protruded semiconductor region, and the third protruded semiconductor region being formed on a substrate; a first transistor including a first source region and a first drain region that are arranged in the first protruded semiconductor region so as to be spaced apart from each other in the first direction, a first channel region provided to the first top surface and the first side surfaces of the first protruded semiconductor region between the first source region and the first drain region, the first channel region having a first corner portion in its upper portion in a section that is perpendicular to the first direction, the first corner portion having a first radius of curvature, a first gate insulating film formed on the first channel region, and a first gate electrode formed on the first gate insulating film; a second transistor including a second source region and a second drain region that are arranged in the second protruded semiconductor region so as to be spaced apart from each other in the second direction, a second channel region provided to the second top surface and the second side surfaces of the second protruded semiconductor region between the second source region and the second drain region, the second channel region having a second corner portion in its upper portion in a section that is perpendicular to the second direction, the second corner portion having a second radius of curvature, a second gate insulating film formed on the second channel region, and a second gate electrode formed on the second gate insulating film; a third transistor including a third source region and a third drain region that are arranged in the third protruded semiconductor region so as to be spaced apart from each other in the third direction, a third channel region provided to the third top surface and the third side surfaces of the third protruded semiconductor region between the third source region and the third drain region, the third channel region having a third corner portion in its upper portion in a section that is perpendicular to the third direction, the third corner portion having a third radius of curvature that is greater than the first radius of curvature and the second radius of curvature, a third gate insulating film formed on the third channel region, and a third gate electrode formed on the third gate insulating film; a first wiring line connected to one of the first source region and the first drain region; a second wiring line connected to one of the second source region and the second drain region; and a third wiring line connected to the first gate electrode and the second gate electrode, the other of the first source region and the first drain region and the other of the second source region and the second drain region being connected to the third gate electrode.

Hereinafter, embodiments will be described with reference to the accompanying drawings.

### First Embodiment

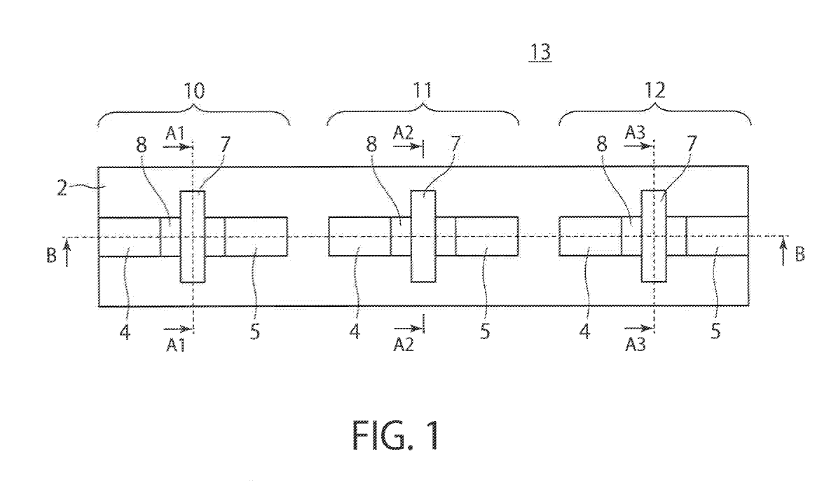

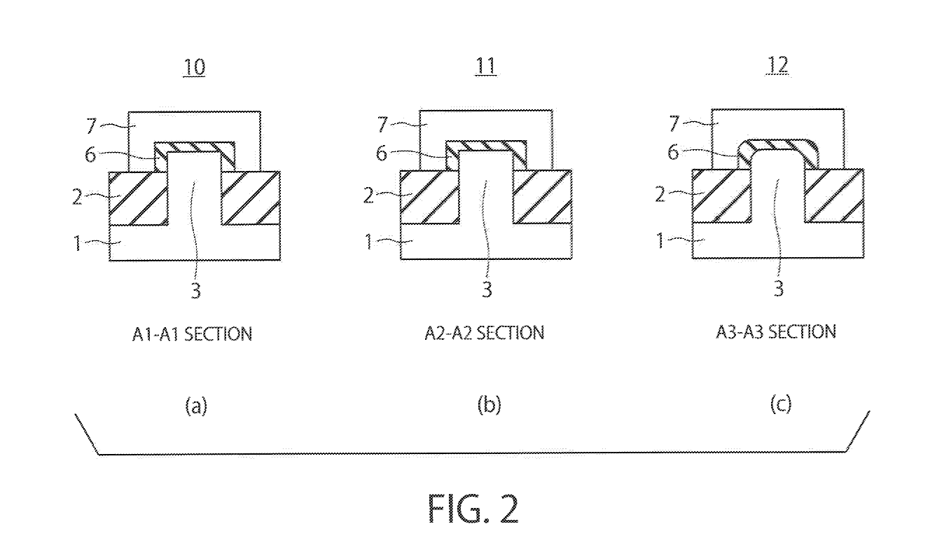

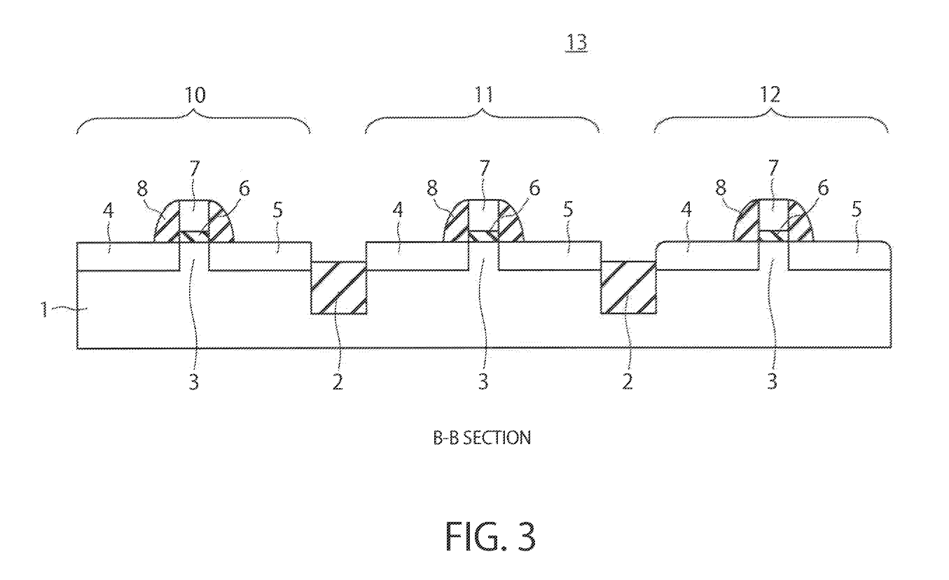

FIGS. 1 to 3 show a semiconductor device according to a first embodiment, FIG. 1 is a plan view, FIGS. 2(a) to 2(c) are cross-sectional views in the gate width direction taken along lines A1-A1, A2-A2, and A3-A3 shown in FIG. 1, respectively, and FIG. 3 is a cross-sectional view in the gate length direction taken along line B-B shown in FIG. 1.

The semiconductor device according to the first embodiment includes a nonvolatile programmable switch (hereinafter also referred to as the “switch”) 13. The switch 13 includes a first memory transistor 10, a second memory transistor 11, and a pass transistor 12. The first memory transistor 10, the second memory transistor 11, and the pass transistor 12 are mounted on a common semiconductor layer, e.g., a silicon semiconductor layer 1. The semiconductor layer 1 may be a silicon on insulator (SOI) layer of an 501 substrate, or a well on a bulk substrate, or a bulk substrate.

The transistors 10, 11, 12 each include a channel region 3, a source region 4, and a drain region 5 formed on the semiconductor layer 1. The source region 4 and the drain region 5 of each transistor are arranged to be spaced apart from each other in the semiconductor layer 1, and a region of the semiconductor layer 1 between the source region 4 and the drain region 5 is a channel region 3, The transistors 10, 11, 12 are isolated from each other by a device isolation film 2 formed on the semiconductor layer 1.

The channel region 3 in the gate width direction is in a shape of a projection having a planar top surface. In the gate length direction, the top surface of the channel region 3 is substantially flush with the top surfaces of the source region 4 and the drain region 5. Specifically, as can be understood from FIGS. 1 to 2(c), there is a step or difference in height between the top surface of the channel region 3 in the gate width direction and the top surface of the device isolation film 2. The channel region 3, the source region 4, and the drain region 5 in each transistor are formed in a protruded region of the semiconductor layer 1. The source region 4 and the drain region 5 are arranged to be spaced apart from each other in the protruded region, and the channel region 3 is arranged between the source region 4 and the drain region 5 to include the top surface of the protruded region and part of the side surfaces of the protruded region.

A gate insulating film 6 is formed to cover the top surface and the side surfaces of the channel region 3. As can be understood from FIGS. 2(a), 2(b), and 2(c), the side surfaces of the channel region 3 can be seen as side surfaces in the section in the gate width direction, i.e., the side surfaces extend along a direction perpendicular to the gate width direction. The gate insulating film 6 is arranged to cover the top surface and part of the side surfaces of the channel region 3. The rest of the side surfaces is covered by the device isolation film 2. A gate electrode 7 is formed above the channel region 3 with the gate insulating film 6 being sandwiched therebetween. A gate sidewall 8 of an insulating material is formed on each side surface of the gate electrode 7 in the gate length direction, i.e., on each side surface of the gate electrode 7 along a direction perpendicular to the gate length direction.

As can be understood from FIGS. 2(a) to 2(c), in this embodiment, the radius of curvature of the corner portions on the top surface of the channel regions 3 of the first memory transistor 10 and the second memory transistor 11 is less than that of the corner portions on the top surface of the pass transistor 12.

The length of the gate electrode 7 in the gate length direction (gate length) is typically from about 10 nm to about 1 μm, and the length of the channel region 3 in the gate width direction (gate width) is about 5 nm to about 1 μm, the thickness of the equivalent oxide film of the gate insulating film 6 is from about 0.5 nm to about 10 nm, and the distance between the top surface of the channel region 3 and the top surface of the device isolation film 2 (the height of the step) is from about 5 nm to about 100 nm. Herein, it is assumed that the length of the gate electrode 7 is about 100 nm, the width of the channel region 3 is about 50 nm, the thickness of the gate insulating film 6 is about 2 nm, and the height of the step between the top surface of the channel region 3 and the top surface of the device isolation film 2 is about 20 nm.

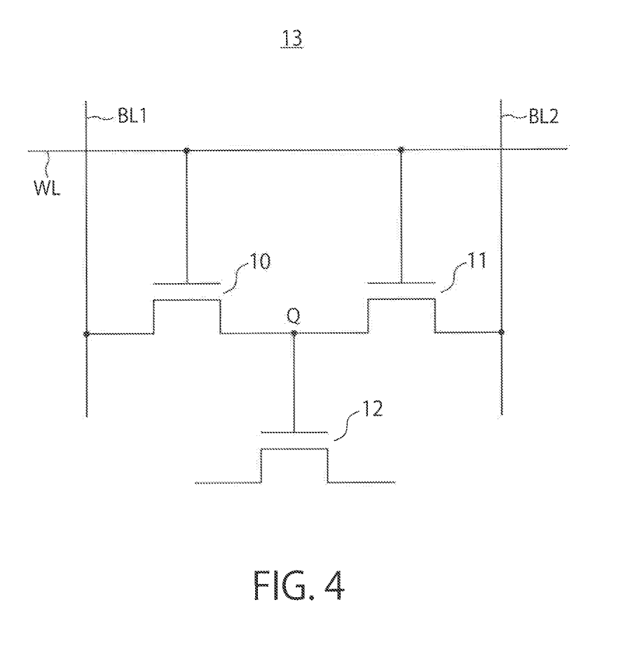

FIG. 4 shows an equivalent circuit of the switch 13 included in the semiconductor device according to the first embodiment. In the switch 13, one of the source and the drain of the first memory transistor 10 is connected to one of the source and the drain of the second memory transistor 11 at the node Q. The other of the source and the drain of the first memory transistor 10 is connected to a bit line BL1, and the other of the source and the drain of the second memory transistor 11 is connected to a bit line BL2. The gates of the first and second memory transistors 10, 11 are connected to a word line WL. The node Q is connected to the gate of the pass transistor 12.

When the switch 13 is normally operating, a voltage of 0 V is applied to the bit line BL1, a power supply voltage is applied to the bit line BL2, a read voltage is applied to the word line WL, and a voltage of 0 V is applied to the semiconductor layer (or well) 1. Depending on the storage state of the first memory transistor 10 and the second memory transistor 11 (i.e., whether the threshold voltage is higher or lower than the read voltage), a voltage of 0 V or a power supply voltage is applied to the gate electrode, i.e., the node Q of the pass transistor 12 to determine whether the pass transistor 12 should be turned on or off.

Next, a write operation of the first and second memory transistors 10, 11 will be described below. For example, when the write operation is performed on the second memory transistor 11 (i.e., the threshold voltage is increased), but not performed on the first memory transistor 10, a voltage of 0 V is applied to the bit line BL1, and a first write voltage (for example, 3.3 V) is applied to the bit line BL2. A second write voltage (for example, 1.2 V) is applied to the word line WL. A third write voltage (for example, −3.3 V) is applied to semiconductor layer (or well) 1. At this time, hot-carrier injection occurs at the end on the bit line BL2 side of the gate insulating film of the second memory transistor 11, by which a write operation is performed. Since the difference in potential between the bit line BL1 and the semiconductor layer (well) 1 of first memory transistor 10 is not sufficient to cause the hot-carrier injection, no write operation is performed to the first memory transistor 10.

In this embodiment, the top surfaces of the channel regions 3 of the memory transistors 10, 11 and the pass transistor 12 are higher than the top surfaces of adjacent portions of the device isolation film 2 by about 20 nm. For this reason, as shown in FIGS. 2(a) to 2(c), the gate electrode 7 covers the corner portions on the top surface of each channel region 3. It is expected that due to such a shape, gate electric field is concentrated on the corner portions of the channel region 3 to accelerate the hot-carrier injection.

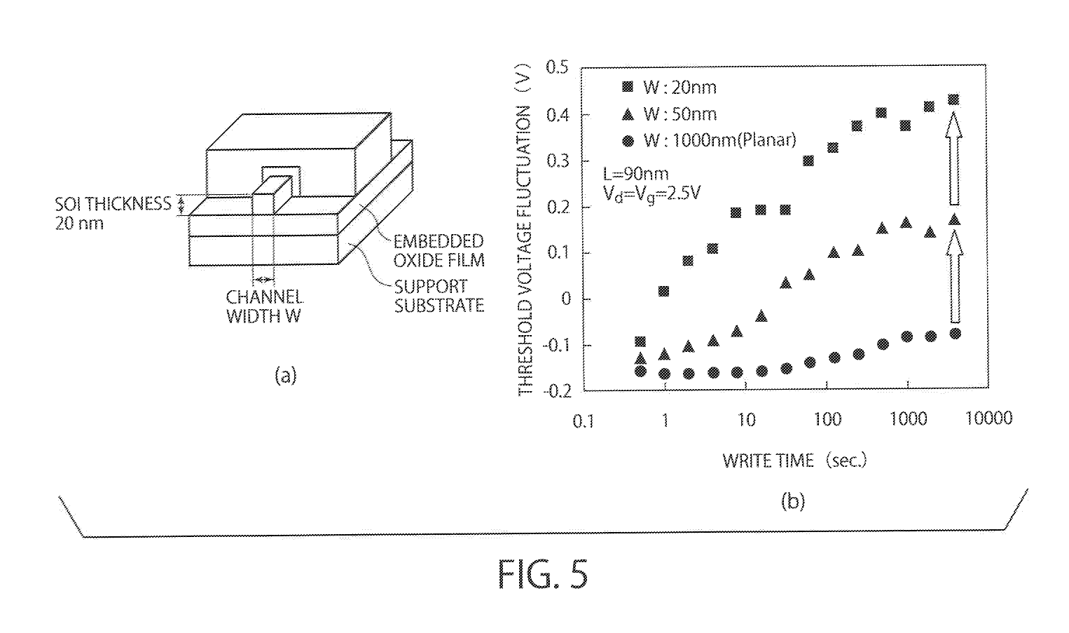

An SOI substrate including a support substrate, an embedded insulating film, and an SOI layer is prepared, and a transistor in which the corner portions of the top surface of the channel region formed in the SOI layer are covered by the gate electrode is actually formed. Three transistors are prepared, each having a different channel region width W. For each transistor, the shifts in threshold voltage caused by the hot-carrier injection are measured. FIG. 5(a) is a perspective view of each transistor formed, and FIG. 5(b) shows the dependence of the threshold voltage shifts (i.e., the amount of hot carrier degradation) of each transistor on the write time, using the channel region width W as a parameter. The respective channel region widths W of the three transistors are 1000 nm, 50 nm, and 20 nm. The black circles, the black triangles, and the black squares represent the measurement results of the threshold voltage shifts of the three transistors. The thickness of the SOI layer in each transistor, i.e., the thickness corresponding to the height of the step between the channel region and the device isolation film of each transistor is 20 nm, and the gate length is 90 nm.

The hot-carrier injection is performed by applying a voltage of 2.5 V to both the gate and the drain of each transistor. As can be understood from FIG. 5(b), as the write time is extended, the change in threshold voltage caused by the hot carrier degradation increases. The change in threshold voltage is more remarkable when the channel width is narrowed. The reason for this is that since the influence of the corner portions in the channel region becomes greater for a transistor having a narrower width, hot-carrier degradation accelerated by the concentration of electric filed on the corner portions considerably increases the threshold voltage of the entire channel region.

In this embodiment, the hot-carrier writing can be performed effectively by reducing the channel width of the first and second memory transistors 10, 11 to less than or equal to 50 nm. As a result, the write time for achieving the same threshold voltage shift can be shortened. Shortening the write time enables reducing the power required for the write operation.

Next, the erase operation of the first and second memory transistors 10, 11 will be described below. For example, in order to erase the second memory transistor 11 (i.e., the threshold voltage is reduced), a voltage of 0 V is applied to the bit line BL1, and a second erase voltage (for example, −3.3 V) is applied to the bit line BL2. A voltage of 0 V is applied to the word line WL, and a voltage of 0 V is applied to the well. At this time, a negative potential difference is caused between the terminal of the second memory transistor 11 connected to the bit line BL2 and the well. Due to this potential difference, hot-hole injection is caused at the end portion on the bit line BL2 side of the gate insulating film of the second memory transistor 11. In this manner, an erase operation is performed. Since no potential difference is caused between the terminal of the first memory transistor 10 connected to the bit line BL1 and the well, no erase operation is performed on this side. Although a voltage of 0 V is applied to the well in the above descriptions, a positive voltage (for example, 3.3 V) can be applied as a third voltage to the well, and a positive voltage (for example, 3.3 V) can be applied as a first voltage to the bit line BL1, and a positive voltage (for example, 1 V) can be applied as the second erase voltage to the bit line BL2.

Conventional nonvolatile programmable switches includes, as a memory transistor, an element having a charge storage layer with a floating gate of polycrystalline silicon or a silicon nitride film formed on a gate insulating film. The total thickness of the gate insulating film and the charge storage layer is typically 10 nm or more. Therefore, such switches require a voltage of 10 V or more to be applied to the word line WL in a write operation.

In contrast, the semiconductor device according to this embodiment does not include a charge storage layer formed on the gate insulating film of the memory transistor. The hot-carrier writing is performed on the gate insulating film (for example, a thermally oxidized film) itself. Therefore, the thickness of the gate insulating film can be typically reduced to about 1 nm, and the voltage to be applied to the word line WL in a write operation can be reduced to about 1.2 V. As a result, the power required to perform the write operation can be considerably reduced as compared to a conventional nonvolatile programmable switch, and a booster circuit for generating a voltage as high as about 10 V can be omitted. Accordingly, the circuit area and the power consumption can be reduced.

The hot-carrier writing can be efficiently performed on the memory transistors 10, 11 by providing a structure in which the top surface of the channel region 3 is higher than the top surface of the device isolation film 2, and the gate electrode 7 covers the corner portions of the channel region 3. However, if such a transistor structure is employed in the pass transistor 12 that does not require the writing, the reliability thereof will be impaired.

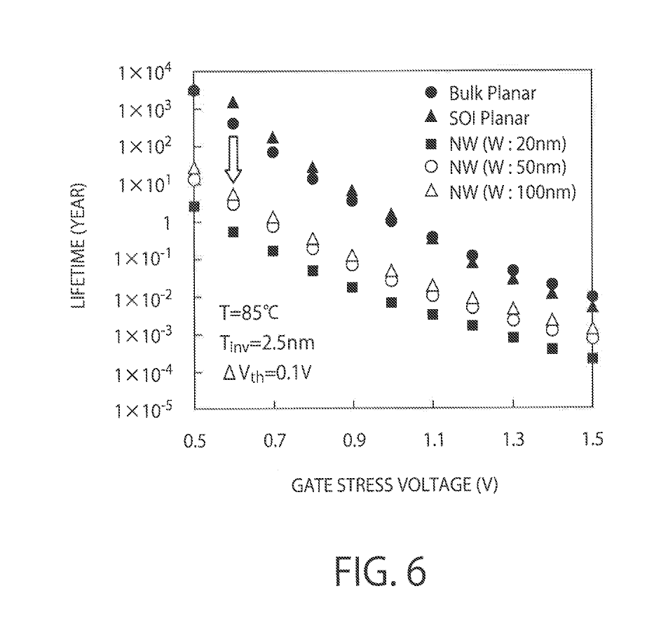

A negative bias temperature instability (NBTI), which is feared to be a cause to impair the reliability of transistors, is evaluated using an SOI transistor that is actually used in the hot-carrier injection test. FIG. 6 is a drawing showing the results of the evaluation of the dependence of lifetime of a transistor determined by the NBTI on the stress voltage, the evaluation being performed on transistors with different channel widths. In each evaluation, a threshold voltage obtained when a stress voltage is continuously applied to the gate of the transistor at a temperature of 85° C. is measured, and the stress time at which the change in threshold voltage exceeds 0.1 V is defined as the end of the lifetime of the transistor. As can be understood from FIG. 6, as the channel width becomes narrower, the lifetime is shortened. The reason for this is the same as the reason in the case of hot-carrier injection, i.e., the charge capturing and the fixed charge generation at the interface state density are accelerated by applying the NBTI stress caused by the concentration of the electric field on the corner portions in the channel region.

In order to prevent the shortening of lifetime, which represents the degradation of the reliability, of the pass transistor 12, it is required to prevent the electric field concentration of the corner portions of the channel region 3. In this embodiment, the corner portions of the top surface of the channel region 3 of the pass transistor 12 are rounded (to increase the radius of curvature) as compared to those of the memory transistors 10, 11, as shown in FIG. 1, in order to prevent the electric field concentration on the corner portions, thereby extending the lifetime of the pass transistor 12 representing the reliability thereof. By setting the radius of curvature of the pass transistor 12 to be, for example, 10 nm or more, the electric field of the corner portions can be reduced to a tenth or less of the case where the radius of curvature is 0. In this manner, it is possible to sufficiently extend the lifetime of the pass transistor 12 representing the reliability thereof. If the radius of curvature of the memory transistors 10, 11 is set to be, for example, 9 nm or less, the electric field of the corner portions can be increased to ten times that of the planar portion or more. In this manner, it is possible to achieve the hot-carrier writing effectively.

### (Manufacturing Method)

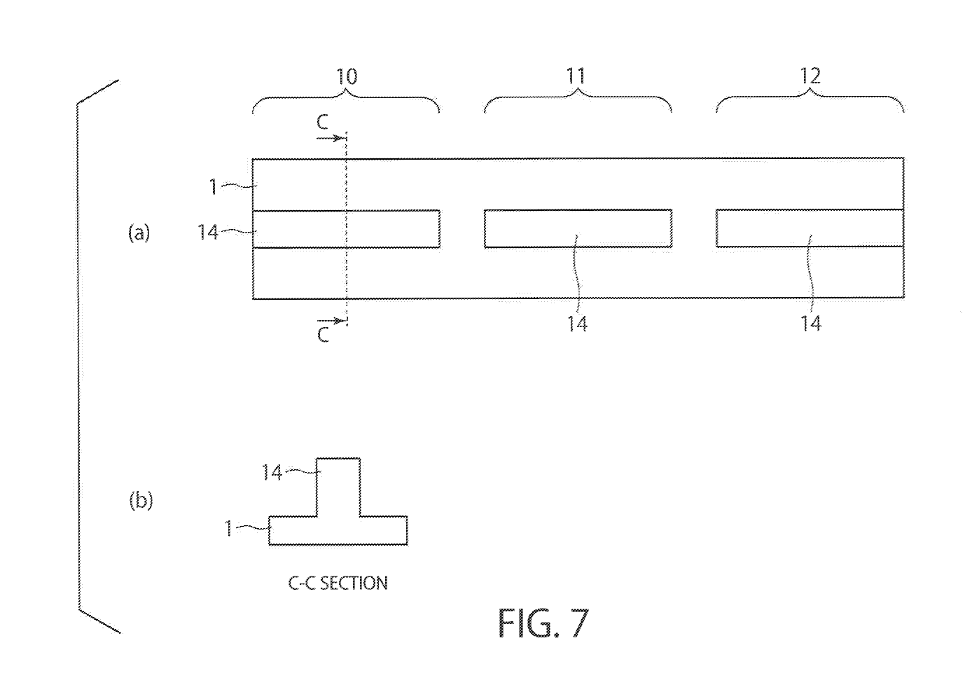

Next, the first example of a method of manufacturing the semiconductor device according to the first embodiment is described with reference to FIGS. 7(a) to 13(c).

First, as shown in FIGS. 7(a) and 7(b), a silicon protruded region 14 to serve as the channel region 3 is formed on the silicon semiconductor layer 1, in each of the regions to form the memory transistors 10, 11 and the pass transistor 12. FIG. 7(a) is a top view, and FIG. 7(b) is a cross-sectional view taken along line CC of FIG. 7(a). The protruded region 14 is formed by lithography and reactive ion etching (RIE) of silicon, using, for example, a hard mask of silicon nitride (not shown). The hard mask is removed after the protruded region 14 is formed.

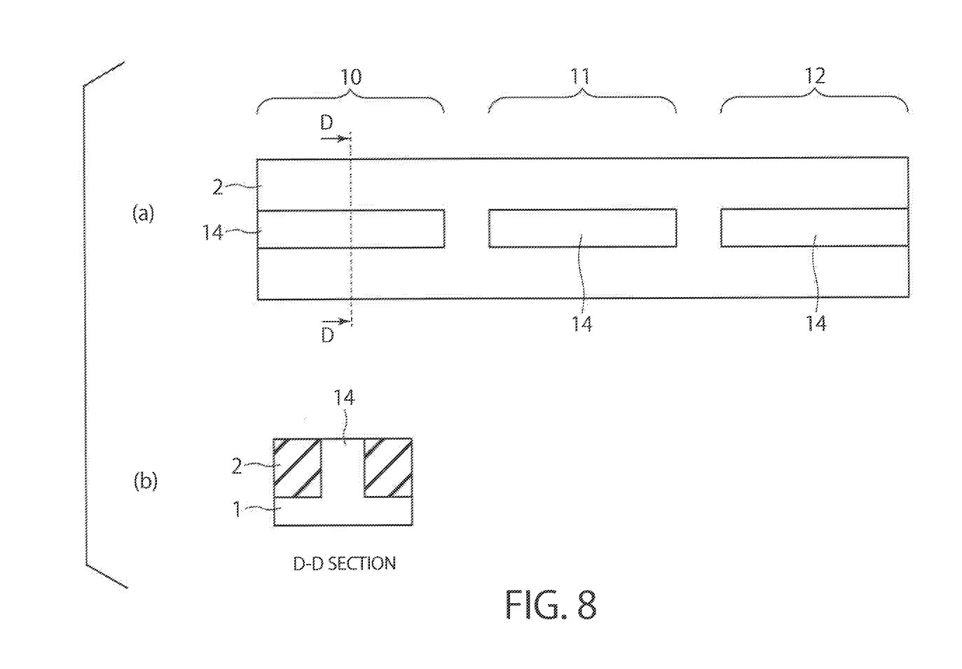

Subsequently, the device isolation film 2 of silicon oxide is formed between the silicon protruded regions 14 as shown in FIGS. 8(a) and 8(b). FIG. 8(a) is a top view, and FIG. 8(b) is a cross-sectional view taken along line DD in FIG. 8(a). The device isolation film 2 is formed by depositing a silicon oxide film and performing chemical mechanical polishing (CMP).

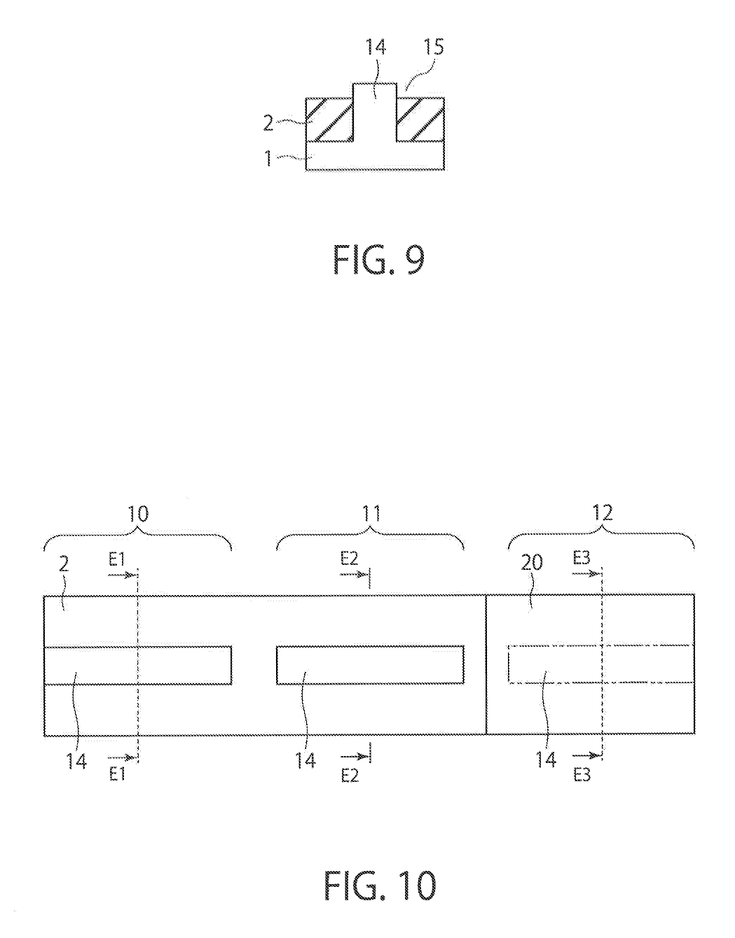

The device isolation film 2 is partially removed by hydrogen fluoride to form a difference in height 15 of about 20 nm between the silicon protruded region 14 and the device isolation film 2, as shown in FIG. 9.

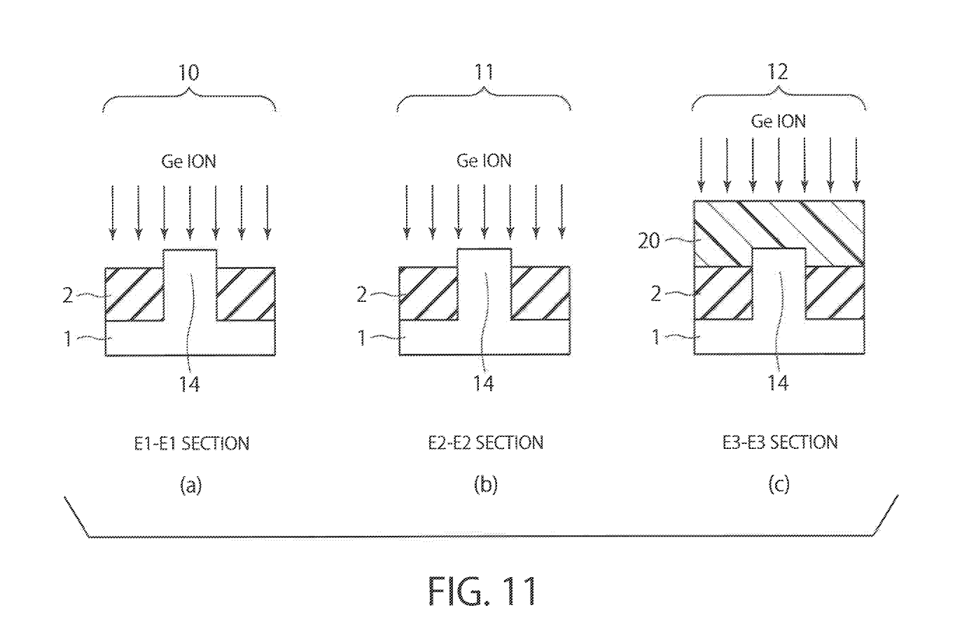

The upper portion of the pass transistor 12 is covered by a resist 20, and ion implantation is performed to form an amorphous silicon surface, as shown in FIGS. 10 to 11(c). FIG. 10 is a top view, and FIGS. 11(a) to 11(c) are cross-sectional views taken along lines E1-E1, E2-E2, and E3-E3 in FIG. 10. Germanium or silicon can be used as the ion species. In order to perform the amorphization process effectively, the ion dose is preferably 1×10¹⁷cm⁻³ or more. In this manner, the selective amorphization of the channel regions 3 of the first memory transistor 10 and the second memory transistor 11 can be performed. Then, a heat treatment is performed under a hydrogen atmosphere.

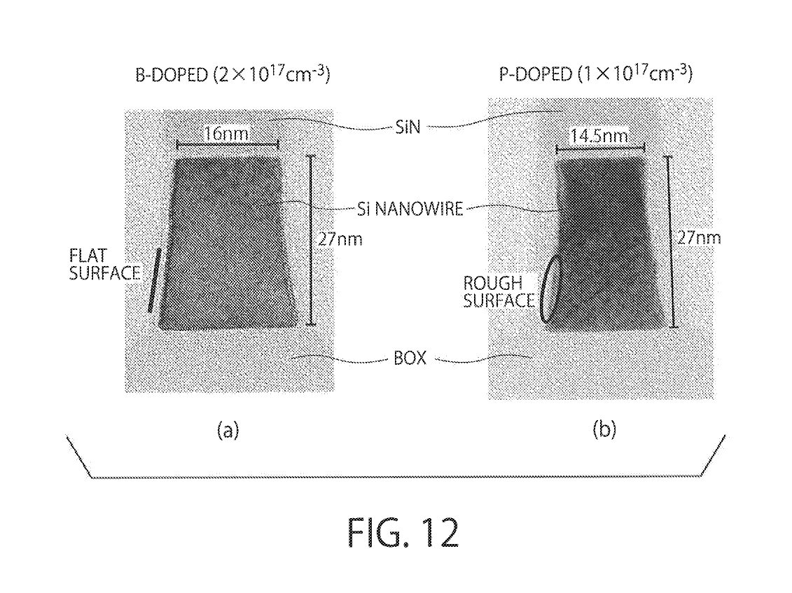

The test result relating to the effect of a heat treatment on amorphous silicon under a hydrogen atmosphere will be described below. FIGS. 12(a) and 12(b) each show a TEM photograph of a section of a silicon nanowire having a height of about 27 nm and a width of about 15 nm, after boron or phosphorus is implanted and hydrogen annealing is performed. The dose amounts of boron and phosphorus are 2×10¹⁷cm⁻³ and 1×10¹⁷cm⁻³, respectively, and the temperature in the hydrogen annealing is 800° C., and the annealing time is 60 seconds. In each silicon nanowire sample used in this test, a silicon nitride film is formed above the silicon nanowire, and a silicon oxide film is formed under the silicon nanowire. Therefore, hydrogen mainly reacts on the side surfaces of the silicon nanowire. Generally, in a hydrogen atmosphere, silicon atoms on the surface fluidize to reveal an atom surface that is stable in terms of energy. In the silicon nanowire to which boron is implanted, a planar surface is formed on each side surface. Thus, it can be understood that fluidization of atoms is caused by the hydrogen annealing (FIG. 12(a)). However, in the silicon nanowire to which phosphorus is implanted, a rough surface is formed on each side surface. Thus, it can be understood that fluidization of atoms is not sufficiently caused by the hydrogen annealing (FIG. 12(b)). The reason for this would be that the effect of forming amorphous silicon is stronger in the phosphorus implantation than in the boron implantation, and therefore the amorphous silicon weakens the effect of fluidization of atoms caused by the hydrogen annealing.

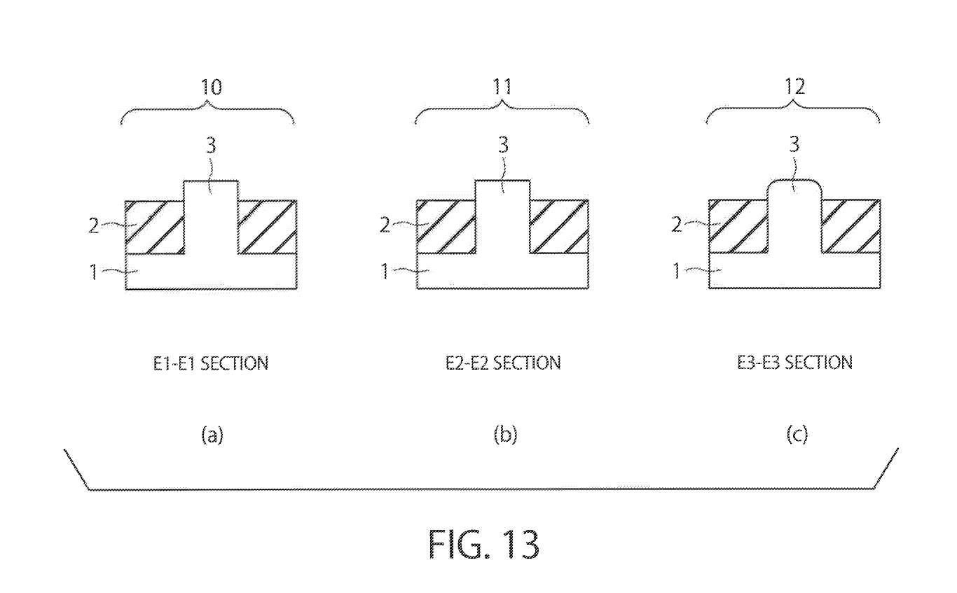

It is considered from this test result that if the selective amorphization is performed only on the channel regions 3 of the first memory transistor 10 and the second memory transistor 11, and then the hydrogen annealing is performed, the corner portions of the channel region 3 of the pass transistor 12, which is not amorphous, are rounded as shown in FIGS. 13(a) to 13(c). As a result the atoms in the corner portions of the channel region 3 of the pass transistor 12 fluidize to make the energy stable. On the other hand, the corner portions of the channel regions 3 of the first memory transistor 10 and the second memory transistor 11, which are amorphous, are not rounded. As a result, the atoms do not fluidize in the corner portions of the channel regions 3 in the first and second memory transistors 10, 11. In this manner, it possible to differentiate the shape of the corner portions of the channel region between the pass transistor 12 and the first and second memory transistors 10, 11, as shown in FIG. 1. FIGS. 13(a), 13(b), and 13(c) are cross-sectional views after the hydrogen annealing, taken along lines E1-E1, E2-E2, and E3-E3 in FIG. 10.

Subsequent to the hydrogen annealing, the gate insulating film 6 is formed on the channel region 3 of each transistor, and the gate electrode 7 is formed thereon. After the gate electrode 7 is processed by lithography and reactive ion etching, the gate sidewalls 8 are formed on both the sides of the gate electrode 7. Then, ions are implanted into the semiconductor layer 1 on both the sides of the gate sidewall 8 to form the source region 4 and the drain region 5. Thereafter, the same process as the process to form an ordinary MOS transistor is performed to form the semiconductor device shown in FIGS. 1 to 3.

A polycrystalline silicon single element film, a single film of a metal-semiconductor compound such as a metal suicide, a metal film of TiN, W, TaC, etc., a multilayer film including a metal-semiconductor compound film and a semiconductor film such as a polycrystalline silicon film, and a multilayer film including a metal film and a semiconductor film such as a polycrystalline silicon film can be used to form the gate electrode 7.

A silicon oxide film, a silicon oxynitride film, a high-K film such as a hafnium oxide film and a zirconium oxide film, and a multilayer film including a silicon oxide film and a high-K film can be used to form the gate insulating film 6.

Both the memory transistors and the pass transistor in the semiconductor device according to this embodiment are typical MOS transistors, and have a common gate stack structure. Accordingly, a process of differentiating the gate stack structure of a memory transistor from that of a pass transistor as in a conventional FPGA using a flash memory, which costs high, is not required in this embodiment. Although a selective amorphous ion implantation should he performed in the process of manufacturing the semiconductor device according to this embodiment in order to differentiate the radius of curvature of the corner portions of the memory transistors from that of the pass transistor, the increase in costs is less than that in the process of differentiating the gate stack structures.

The typical width of the channel region 3 (channel width) of the semiconductor device according to this embodiment is 50 nm or less. Since the channel region 3 has a step portion having a height of about 20 nm in the width direction, the effective channel width is, for example, 90 nm, i.e., the sum of 50 nm, the width, and two times 20 nm, the height. Therefore, the current amount per the same layout area can be increased as compared to the case in which a planar, i.e., stepless transistor is used as in a conventional FPGA, which leads to a decrease in the area of the chip.

The semiconductor device according to this embodiment employs a transistor with a three-dimensional structure having a step in the channel region. However, since this embodiment does not use an SOI substrate like a conventional three-dimensional transistor but uses a bulk substrate, the processing costs can be reduced.

The semiconductor device according to this embodiment has the Tri-gate transistor structure, in which a current flows through both the top surface and the side surfaces of the channel region 3. However, in the fin-FET structure, in which a thick insulating film is provided on the top surface of the channel region 3 so that no current flows through the top surface of the channel region 3, the corner portions of the channel region are not exposed, resulting in that the effect of electric field concentration is weakened. Therefore, in the fin-FET structure, the memory characteristic improving effect (hot-carrier writing efficiency improving effect) as in this embodiment cannot be obtained.

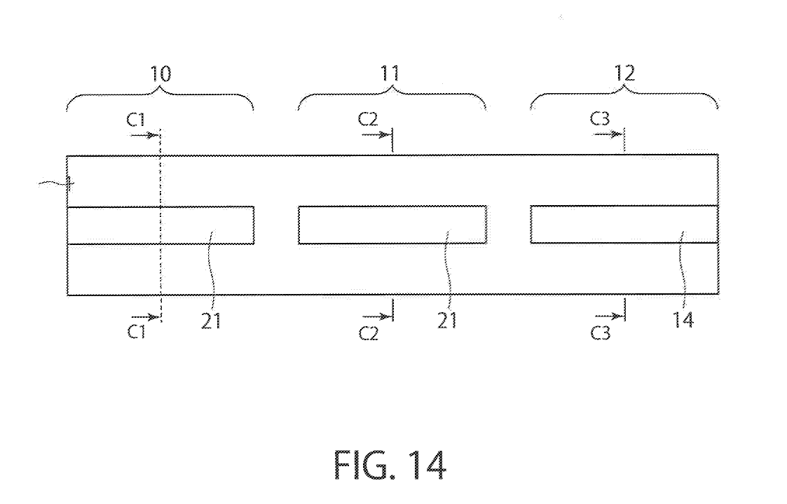

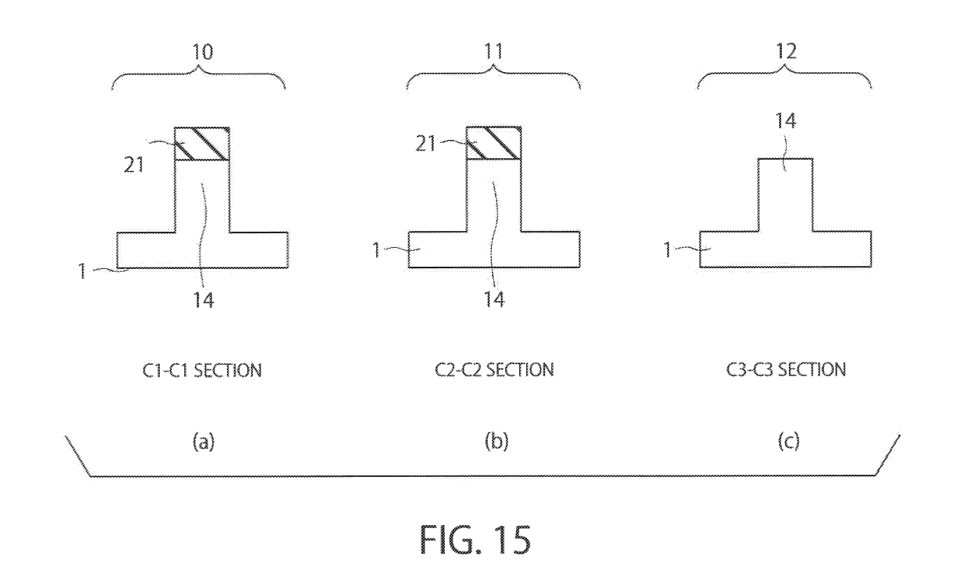

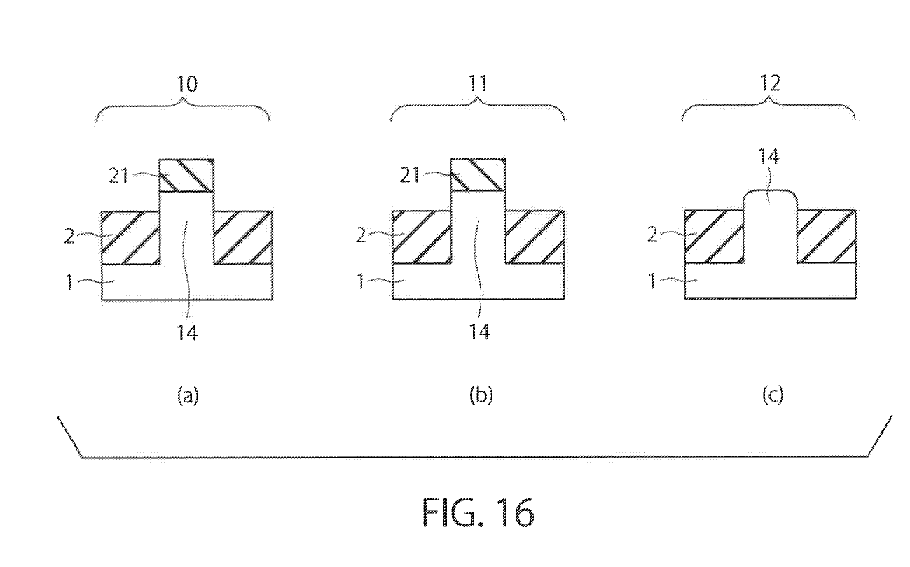

Next, the second example of the method of manufacturing a semiconductor device according to the first embodiment will be described below. As in the case of the first example of the manufacturing method shown in FIGS. 7(a) and 7(b), the silicon protruded region 14 is formed on the silicon semiconductor layer 1. A hard mask of silicon nitride is used to form the protruded region 14. In the second example, the hard mask 21 used to from the protruded region 14 is left on the first and second memory transistors, but selectively removed from the pass transistor 12 (FIGS. 14 to 15(c)). The selective removal is performed by lithography and reactive ion etching or wet etching of the silicon nitride film. FIG. 14 is a top view, and FIGS. 15(a), 15(b), and 15(c) are cross-sectional views taken along lines C1-C1, C2-C2, and C3-C3 in FIG. 14.

Thereafter, as in the case of the first example, the device isolation film 2 is deposited, flattened by CMP, partially removed by hydrogen fluoride, and heat treated under a hydrogen atmosphere. As a result, the corner portions of the channel region 3 of the pass transistor 12 are rounded, but the corner portions of the first memory transistor 10 and the second memory transistor 11, the top surfaces of which are covered by the hard mask 21, are not rounded. Then, the hard mask 21 is removed by, for example, hot phosphoric acid etching. After this point, the same processes as those in the first example are performed.

As described above, according to the first embodiment, the gate insulating films of the first memory transistor 10, the second memory transistor 11, and the pass transistor 12 have the same structure, and charges are stored in the gate insulating films. Therefore, it is possible to prevent an increase in manufacturing costs of a memory embedding process and to reduce the write current. Furthermore, since the gate electrode covers the corner portions of the channel region in each of the first memory transistor 10 and the second memory transistor 11, the hot-carrier writing can be effectively performed on the first and second memory transistors by injecting hot-carriers into their gate insulating films. Because the corner portions of the channel region in the pass transistor 12 are rounded, if hot carriers are also injected into the gate insulating film of the pass transistor 12, the life time representing the reliability of the pass transistor 12 is not shortened.

### Second Embodiment

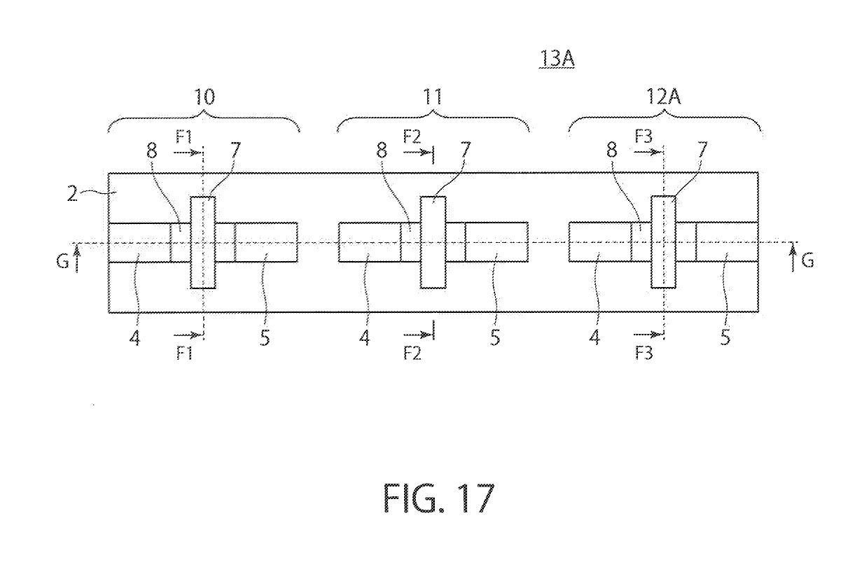

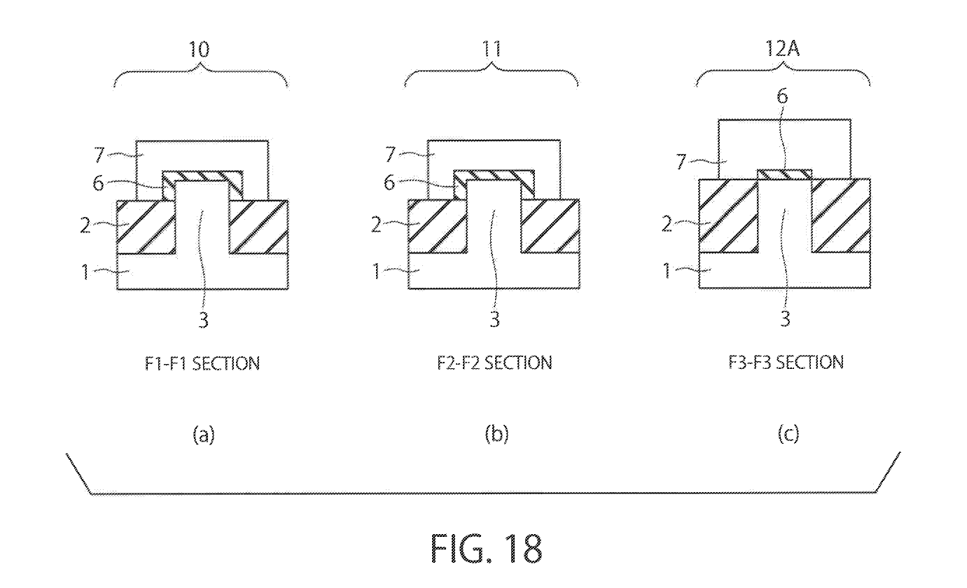

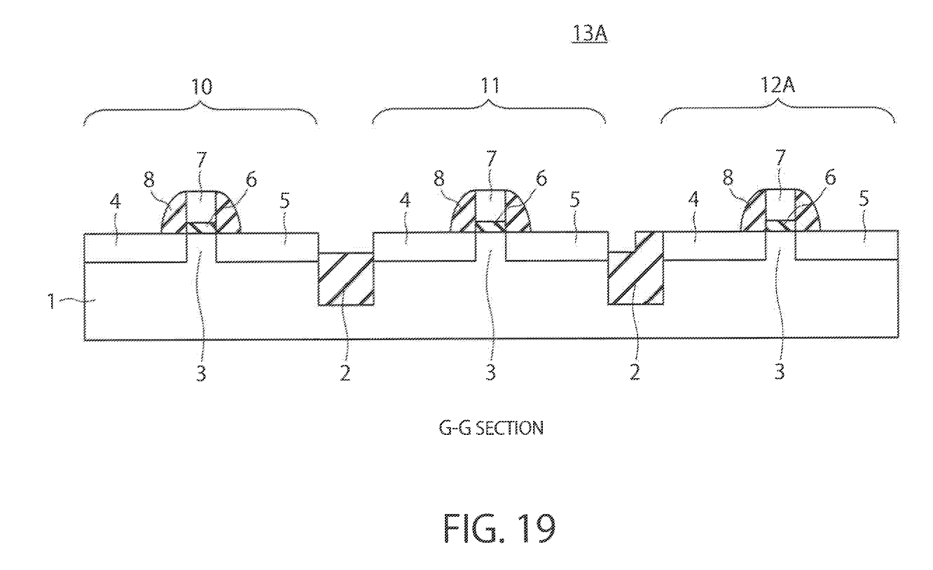

FIGS. 17 to 19 show a semiconductor device according to the second embodiment. FIG. 17 is a plan view, FIGS. 18(a) to 18(c) are cross-sectional views in the gate width direction taken along line F1-F1, F2-F2, and F3-F3 in FIG. 17, and FIG. 19 is a cross-sectional view in the gate length direction taken along line G-G in FIG. 17

The semiconductor device according to the second embodiment includes a switch 13A. The switch 13A is obtained by replacing the pass transistor 12 of the switch 13 in the first embodiment with a pass transistor 12A. In the pass transistor 12A, the top surface of the device isolation film 2 is at the same height as or higher than the top surface of the channel region 3. A gate insulating film 6 is formed on the top surface of the channel region 3, and a gate electrode 7 is formed on the gate insulating film 6. Gate sidewalls 8 are formed on the sides of the gate electrode 7, and the source region 4 and the drain region 5 are formed in the semiconductor layer 1 on the sides of the gate sidewalls 8.

In each of the first and second memory transistors 10, 11, the top surface of the device isolation film 2 is lower than the top surface of the channel region 3, as in the case of the first embodiment. As a result, the top surface of the device isolation film 2 in each of the first and second memory transistors 10, 11 is located to be lower than the top surface of the device isolation film 2 of the pass transistor 12A (FIGS. 18(a), 18(b), and 18(c)).

Typically, the length (gate length) of the gate electrode 7 is approximately 10 nm to 1 μm, the width of the channel region 3 is approximately 5 nm to 1 μm, the thickness of an equivalent oxide film of the gate insulating film 6 is approximately 0.5 nm to 10 nm, and the difference in height between the top surface of the channel region 3 and the top surface of the device isolation film 2 in each of the first memory transistor 10 and the second memory transistor 11 is approximately 5 nm to 100 nm.

The equivalent circuit of the switch 13A of the second embodiment is the same as that of the switch 13 of the first embodiment. The write method and the erase method are also the same.

As in the first embodiment, in each of the memory transistors 10, 11, the top surface of the channel region 3 is higher than the top surface of the device isolation film 2, and the gate electrode covers the corner portions of the top surface of the channel region. As a result, the electric field concentrates on the corner portions of the channel region 3, so that the hot-carrier writing can be effectively performed. On the other hand, in the pass transistor 12A of the second embodiment, the top surface of the channel region 3 in the channel width direction is substantially at the same height as the top surface of the device isolation film 2 to form a so-called planar transistor structure. Accordingly, it is possible to prevent the electric field concentration of the corner portions of the channel region, thereby preventing the degradation of reliability.

Like the first embodiment, no charge storage layer is formed on the gate insulating film of each of the memory transistors 10, 11, and hot carriers are directly injected in the gate insulating film (for example, a thermally oxidized film) in the second embodiment. Accordingly, the thickness of the gate insulating film can be typically reduced to about 1 nm, and the voltage to be applied to the word line WL in the write operation can be reduced to about 1.2 V. As a result, the power required for the write operation can be considerably reduced as compared to the conventional cases, and a booster circuit, which generates a voltage of as high as about 10 V, can be eliminated. Therefore, it is possible to reduce the circuit area and to reduce the power consumption.

Next, a method of manufacturing the semiconductor device according to the second embodiment will be described below.

In this method, the processes to form the protruded regions 14 of silicon on the silicon layer 1 and to form the device isolation film 2 between adjacent protruded regions 14 are the same as those in the method of manufacturing the semiconductor device according to the first embodiment.

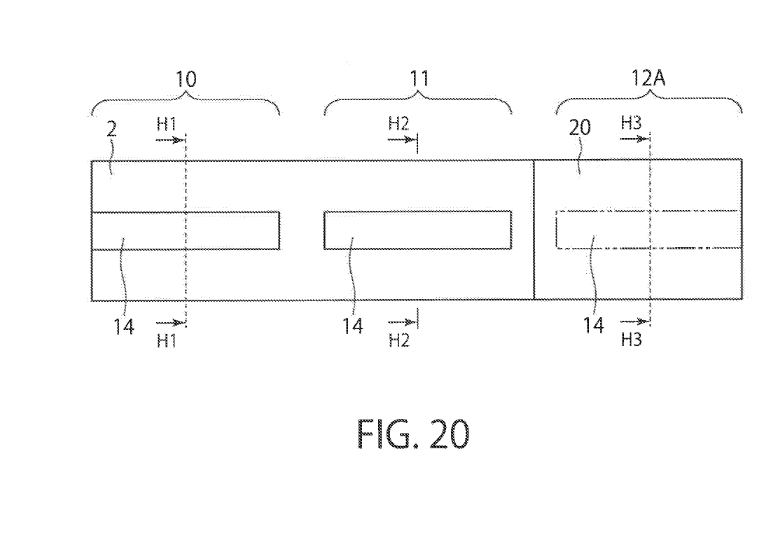

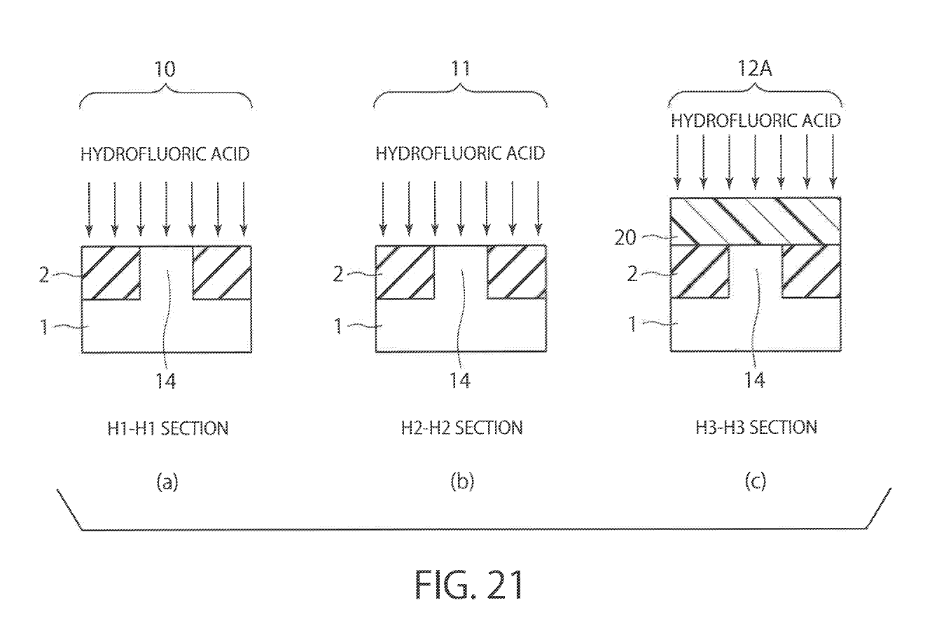

Subsequently, as shown in FIGS. 20 to 21(c), a treatment with a buffered hydrogen fluoride solution is performed with the top surface of the pass transistor 12A being covered by a resist 20. As a result, the device isolation films 2 on both the sides of the channel region 3 of the pass transistor 12A are not removed, but the device isolation films 2 on both the sides of the channel region 3 in each of the first memory transistor 10 and the second memory transistor 11 are removed to form a difference in height 15 of about 20 nm between the channel region 3 and the device isolation film 2 as in the case shown in FIG. 9.

Thereafter, the gate insulating film 6 is formed on the channel region 3 of each transistor, and the gate electrode 7 is formed on the gate insulating film 6. After the gate electrode 7 is processed by lithography and reactive ion etching, the gate sidewalls 8 are formed on both the sides of the gate electrode 7. Ions are injected into the semiconductor layer 1 on both the sides of the gate sidewall 8 to form the source region 4 and the drain region 5. Then, the same process as those for a typical MOS transistor is performed to form the semiconductor device shown in FIGS. 17 to 19.

Like the first embodiment, both the memory transistors 10, 11 and the pass transistor 12 in the semiconductor device according to the second embodiment are typical MOS transistors, and have substantially the same gate stack structure. Accordingly, a process of differentiating the gate stack structure of the memory transistors 10, 11 from that of the pass transistor 12 as in a conventional FPGA using a flash memory, which costs high, is not required in this embodiment. Although a selective etching of the device isolation film is required in the process of manufacturing the semiconductor device according to this embodiment in order to change the difference in height between the channel regions 3 of the memory transistors 10, 11 and the device isolation film 2 and the difference in height between the channel region 3 of the pass transistor 12 and the device isolation film 2, the increase in costs to perform this is less than that in the process of changing the gate stack structures.

As described above, according to the second embodiment, the gate insulating films of the first memory transistor 10, the second memory transistor 11, and the pass transistor 12 have the same structure, and charges are stored in the gate insulating films. Therefore, it is possible to prevent an increase in manufacturing costs of a memory embedding process, and to reduce the write current. Furthermore, since the gate electrode covers the corner portions of the channel region in each of the first memory transistor 10 and the second memory transistor 11, the hot-carrier writing can be effectively performed on the first and second memory transistors by injecting hot-carriers into the gate insulating films. Because the pass transistor 12 has a planar transistor structure, it is possible to prevent the electric field concentration on the corner portions of the channel region, thereby preventing the degradation of the reliability.

### Third Embodiment

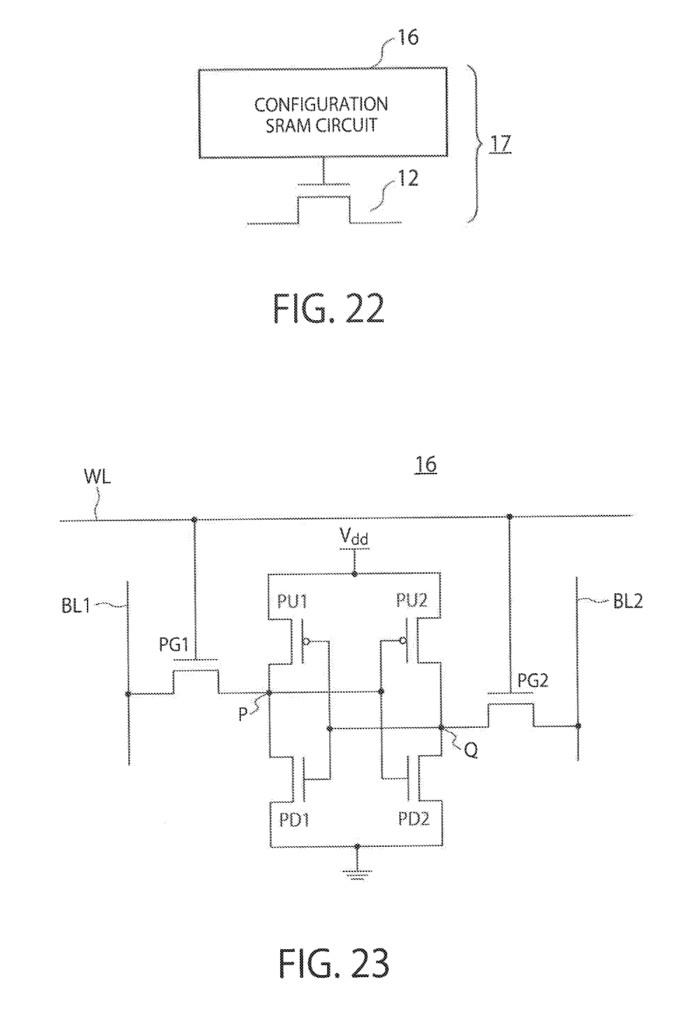

FIG. 22 shows a semiconductor device according to the third embodiment, which is a programmable switch 17 including a pass transistor 12 and a configuration SRAM circuit 16.

FIG. 23 shows a specific example of the configuration SRAM circuit 16, which typically has four n-type MOS transistors PD1, PD2, PG1, PG2 and two p-type MOS transistors PU1, PU2, The number of transistors constituting the SRAM circuit may be less than six or greater than six. In the SRAM circuit 16 shown in FIG. 23, the p-type MOS transistor PU1 and the n-type MOS transistor PD1 form a first inverter, and the p-type MOS transistor PU2 and the n-type MOS transistor PD2 form a second inverter. The first inverter and the second inverter are cross-connected. The source of each of the p-type MOS transistors PU1, PU2 forming the first inverter or second inverter is connected to a power supply Vdd, and the source of each of the n-type MOS transistors PD1, PD2 is connected to the ground.

The drain of each of the p-type MOS transistor PU1 and the n-type MOS transistor PD1 is connected to a node P that is connected to one of the source and the drain of the n-type MOS transistor PG1, The other of the source and the drain of the n-type MOS transistor PG1 is connected to the bit line ELI. The gate of the n-type MOS transistor PG1 is connected to the word line WL.

The drain of each of the p-type MOS transistor PU2 and the n-type MOS transistor PD2 is connected to a node Q that is connected to one of the source and the drain of the n-type MOS transistor PG2. The other of the source and the drain of the n-type MOS transistor PG2 is connected to the bit line BL2. The gate of the n-type MOS transistor PG2 is connected to the word line WL. The node Q of the SRAM circuit 16 is connected to the gate electrode 7 of the pass transistor 12.

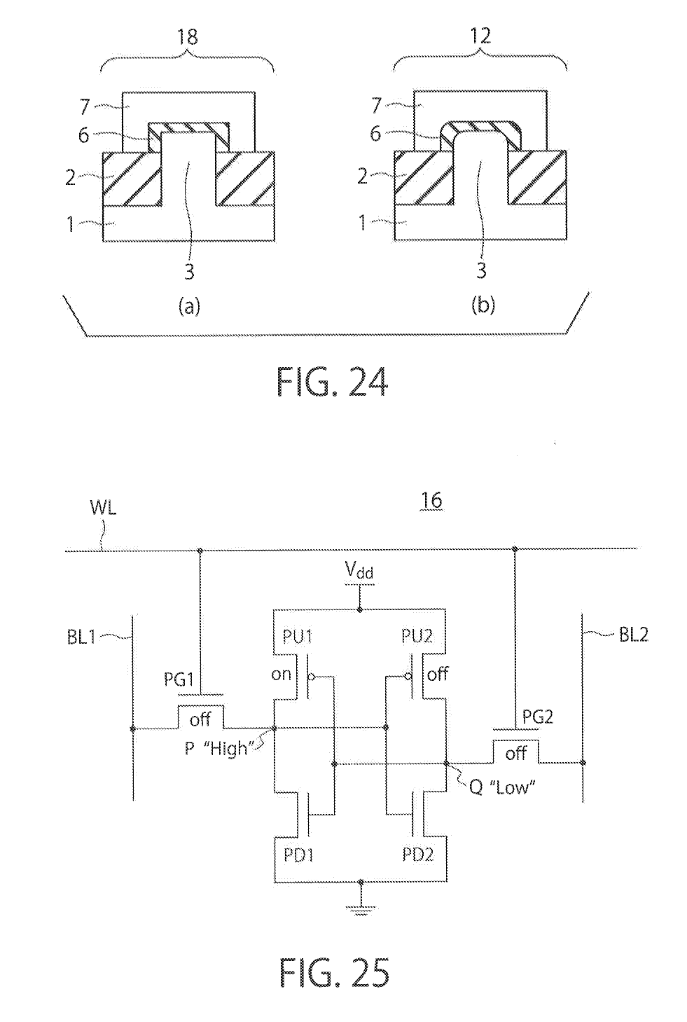

FIGS. 24(a) and 24(b) show the sections in the gate width direction of one of the transistors 18 constituting the SRAM circuit 16 and the pass transistor of the semiconductor device according to the third embodiment. Although the pass transistor 12 and the transistor 18 of the SRAM circuit 16 are apparently in the same section in FIGS. 24(a) and 24(b), these transistors are not necessarily formed in the same section in the actual device. If the SRAM circuit 16 has a configuration shown in FIG. 23, the transistor 18 represents each of the six transistors PD1, PD2, PU1, PU2, PG1, PG2.

The pass transistor 12 and the transistors 18 constituting the SRAM circuit 16 are formed on the same substrate. The n-type MOS transistors and the pass transistor 12 are formed on a p-well of the substrate, and the p-type MOS transistors are formed on an n-well of the substrate. Each transistor 18 includes a device isolation film 2, a channel region 3, a source region 4, and a drain region 5, and the top surface of the channel region 3 is higher than the top surface of the device isolation film 2, A gate insulating film 6 is formed on the top surface and the side surfaces of the channel region 3, and a gate electrode 7 is formed on the gate insulating film 6, Gate sidewalls 8 are formed on both the sides of the gate electrode 7, and a source region 4 and a drain region 5 are formed in the semiconductor layer 1 on both the sides of the gate sidewalls 8. The pass transistor 12 and the transistors 18 constituting the SRAM circuit 16 are formed in different protruded semiconductor regions. Thus, in each protruded semiconductor region, the channel region 3, the source region 4, and the drain region 5 of the corresponding transistor are formed, The channel region 3 is formed to include the top surface and the side surfaces of the protruded semiconductor region. Incidentally, the transistors that have the same conductivity type in the SRAM circuit 16 may be formed in the same protruded semiconductor region.

The radius of curvature of the corner portions of the channel region 3 in each of the transistors 18 constituting the SRAM circuit 16 is less than that of the corner portions of the channel region 3 of the pass transistor 12.

Typically, the gate length of the gate electrode 7 is approximately 10 nm to 1μm, the channel width of the channel region 3 is approximately 5 nm to 1 μm, the thickness of the equivalent oxide film of the gate insulating film 6 is approximately 0.5 nm to 10 nm, and the difference in height between the top surface of the channel region 3 and the top surface of the device isolation film region 2 is approximately 5 nm to 100 nm.

The operation of the semiconductor device according to the third embodiment will be described below. In the initial stage, this semiconductor device is used as an ordinary volatile FPGA, and in a stage before which the logic function of the FPGA is determined, this semiconductor device is used as a nonvolatile FPGA. How the volatile FPGA and the nonvolatile FPGA are operated will be described step by step.

First, in the initial stage, the logic function of the FPGA is designed while the storage state of the configuration SRAM circuit 16 (i.e., the voltage value of the node Q and the gate voltage value of the pass transistor 12) is arbitrarily changed.

After the design is completed and the logic function of the FPGA is determined, the storage state of the configuration SRAM circuit 16 is made nonvolatile. FIG. 25 shows a circuit for explaining a method of making the configuration SRAM circuit 16 of the third embodiment nonvolatile. It is assumed that in the storage state determined after the design is completed, the node P is at a Low level, and the node Q is at a High level. Then, the write operation is performed on the SRAM circuit 16 to make the storage state opposite to the storage state that have been determined, i.e., the node P is at the High level, and the node Q is at the Low level. In this state, a voltage of 0 V is applied to the word line WL to turn off the n-type MOS transistor PG1 and the n-type MOS transistor PG2, and to increase the power supply voltage Vdd to a voltage of, for example, 3.3 V that is higher than a normal voltage of, for example, 1V, Since the p-type MOS transistor PU1 is still in the on state, the voltage of the node P follows the power supply voltage and increases to approximately 3.3 V, and since the p-type MOS transistor PU2 is still in the off state, the voltage of the node Q remains zero. As a result, 0 V is applied to the gate and 3.3 V is applied to each of the drain and the source of the p-type MOS transistor PU1, and a high electric field is applied to the gate insulating film of the p-type MOS transistor PU1. Due to the Fowler-Nordheim (FN) stress or NBTI stress, positive charges are injected into the gate insulating film of the p-type MOS transistor PU1 to increase the threshold voltage in the negative direction. As a result, the threshold voltage of the p-type MOS transistor PU1 becomes sufficiently higher than the threshold voltage of the p-type MOS transistor PU2. Accordingly, if the power supply voltage Vdd is reduced to zero, and then increased to a normal operation voltage, the node P should be at the Low level, and the node Q should be at the High level.

In the above descriptions, the write operation using the FN stress or NBTI stress is described as an example. Alternatively, a write operation using hot-carrier stress can also be considered.

Like the memory transistors of the first embodiment, each of the transistors constituting the SRAM circuit 16 has a structure in which the top surface of the channel region 3 is higher than the top surface of the device isolation film 2, and the gate electrode covers the corner portions of the channel. Accordingly, an electric field concentration is caused at the corner portions of the channel region 3, resulting in that the writing to the gate insulating film 6 using the voltage stress (by changing the threshold voltage) can be efficiently performed to shorten the write time to obtain the same threshold voltage change. By shortening the write time, the power required to the writing can be reduced.

The pass transistor 12 that does not require a write operation has a radius of curvature that is larger than that of the transistors constituting the SRAM circuit 16 as in the case of the first embodiment. This prevents the electric field concentration of the corner portions of the channel region 3, thereby extending the lifetime representing the reliability of the pass transistor.

If the channel width of the transistor is 50 nm and the channel region 3 has a step in the width direction with a height of approximately 20 nm in the semiconductor device according to the third embodiment, the effective channel width is 90 nm (the sum of 50 nm, the width, and twice 20 nm, the height of the step). Therefore, the current amount per the same layout area can be increased as compared to a conventional FPGA using a planar (stepless) transistor. Accordingly, the chip area can be reduced. Furthermore, since the effective channel width per the same layout area is wide, the threshold voltage shift can be reduced. Therefore, the stability in operation of the SRAM circuit 16 can be improved, and the minimum operating voltage can be reduced.

The method of manufacturing the semiconductor device according to the third embodiment is the same as the method of manufacturing the semiconductor device according to the first embodiment except for the way of connecting transistors (circuit configuration).

As described above, according to the third embodiment, the gate insulating films of the transistors 18 of the SRAM circuit 16 and the pass transistor 12 have the same structure and store electric charges. Accordingly, it is possible to prevent an increase in the manufacturing costs in a memory embedding process, and to reduce the writing voltage.

Furthermore, since the gate electrode covers the corner portions of the channel region, the hot carrier writing can be performed efficiently on the transistor by by injecting the hot carriers into the gate insulating film of each transistor in the SRAM circuit 16. Since the corner portions of the channel region of the pass transistor 12 are rounded, the hot carriers injected into the gate insulating film of the pass transistor 12 do not shorten the lifetime representing the reliability of the pass transistor 12.

### Fourth Embodiment

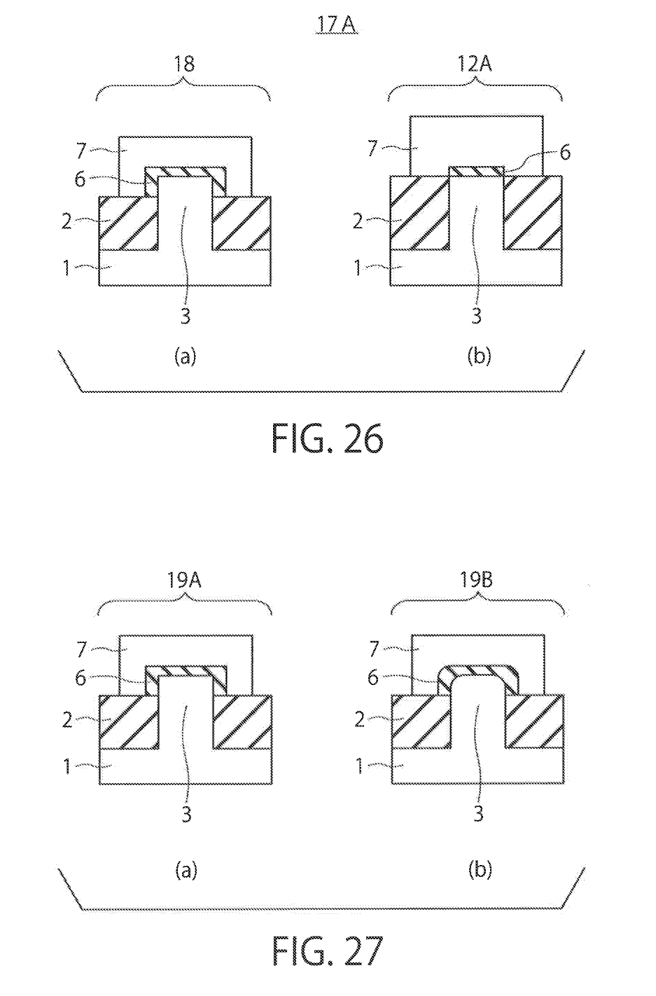

A semiconductor device according to the fourth embodiment will be described with reference to FIGS. 26(a) and 26(b). This semiconductor device is obtained by replacing the pass transistor 12 in the programmable switch 17 of the third embodiment with a pass transistor 12A to form a programmable switch 17A including the pass transistor 12A and a configuration SRAM circuit 16.

FIGS. 26(a) and 26(b) are cross-sectional views in the gate width direction of one of the transistors constituting the SRAM circuit 16 and the pass transistor of the semiconductor device according to the fourth embodiment. FIGS. 26(a) and 26(b) show that the pass transistor 12A and the transistor 18 constituting the SRAM circuit 16 are in the same section. However, they are not necessarily formed in the same section in the actual device. If the SRAM circuit 16 has a configuration as shown in FIG, 23, for example, the transistor 18 represents the six transistors PD1, PD2, PU1, PU2, PG1, and PG2.

The transistor 18 constituting the SRAM circuit includes, for example, a device isolation film 2, a channel region 3, a source region 4, and a drain region 5 formed on a silicon semiconductor layer 1, the top surface of the device isolation film 2 being lower than the top surface of the channel region 3. A gate insulating film 6 is formed to cover the top surface and the side surfaces of the channel region 3, and a gate electrode 7 is formed on the gate insulating film 6. Gate sidewalls 8 are formed on both the sides of the gate electrode 7, and a source region 4 and a drain region 5 are formed in the semiconductor layer 1 on the both sides of the gate sidewalls 8 (FIG. 26(a)).

The pass transistor 12A has the same structure as the pass transistor 12A of the second embodiment shown in FIG. 18(c). Specifically, the pass transistor 12A includes, for example, a device isolation film 2, a channel region 3, a source region 4, and a drain region 5 formed on the silicon semiconductor layer 1, the top surface of the device isolation film 2 being higher than or at the same height as the top surface of the channel region 3. A gate insulating film 6 is formed on the top surface of the channel region 3, and a gate electrode 7 is formed on the gate insulating film 6. Gate sidewalls 8 are formed on both the sides of the gate electrode 7, and the source region 4 and the drain region 5 are formed in the semiconductor layer 1 on both the sides of the gate sidewalls 8 (FIG. 26(b)). As a result, the top surface of the device isolation film 2 of the transistor 18 constituting the SRAM circuit 16 is lower than the top surface of the device isolation film 2 of the pass transistor 12A.

The equivalent circuit and the operation method of the programmable switch 17A of the fourth embodiment are the same as those of the programmable switch 17 of the third embodiment.

Like the memory transistors of the third embodiment, each of the transistors 18 constituting the SRAM circuit has a structure in which the top surface of the channel region 3 is higher than the top surface of the device isolation film 2, and the gate electrode covers the corner portions of the channel region 3. Accordingly, an electric field concentration is caused at the corner portions of the channel region 3, resulting in that the writing operation using the voltage stress (by changing the threshold voltage) can be efficiently performed. The pass transistor 12A has a so-called planar transistor structure, in which the top surface of the channel region 3 is at substantially the same height as the top surface of the device isolation film 2 in the width direction. Accordingly, it is possible to prevent the electric field concentration on the corner portions of the channel region 3, thereby preventing the degradation of reliability.

The method of manufacturing the semiconductor device according to the fourth embodiment is the same as the method of manufacturing the semiconductor device according to the second embodiment except for the way of connecting transistors (circuit configuration).

As described above, according to the fourth embodiment, the gate insulating films of the transistors 18 of the SRAM circuit 16 and the pass transistor 12A have the same structure and store electric charges. Accordingly, it is possible to prevent an increase in the manufacturing costs in a memory embedding process, and to reduce the writing voltage.

### Fifth Embodiment

A semiconductor device according to the fifth embodiment will be described with reference to FIGS. 27(a) and 27(b). The semiconductor device according to the fifth embodiment is a CMOS circuit including an n-type MOS transistor 19A and a p-type MOS transistor 19B. FIGS. 27(a) and 27(b) are cross-sectional views of the n-type MOS transistor 19A and the p-type MOS transistor 19B in the gate width direction, respectively, Although the n-type MOS transistor 19A and the p-type MOS transistor 19B are apparently in the same section, they are not necessarily formed in the same section in an actual device.

The n-type MOS transistor 19A has the same structure as the first and second memory transistors 10, 11 of the first embodiment, but the channel region 3 is replaced with a p-type semiconductor layer and the source region 4 and the drain region 5 are replaced with n-type impurity layers. The p-type MOS transistor 19B has the same structure as the pass transistor 12 of the first embodiment, but the channel region 3 is replaced with an n-type semiconductor layer and the source region 4 and the drain region 5 are replaced with p-type impurity layers.

Each transistor includes a device isolation film region 2, a channel region 3, a source region 4, and a drain region 5; the top surface of the channel region 3 being higher than the top surface of the device isolation film 2. A gate insulating film 6 is formed to cover the top surface and the side surfaces of the channel region 3, and a gate electrode 7 is formed on the gate insulating film 6. Gate sidewall 8 are formed on both the sides of the gate electrode 7, and the source region 4 and the drain region 5 are formed in the semiconductor layer 1 on both the sides of the gate sidewall 8. The radius of curvature of the corner portions of the channel region 3 of the n-type MOS transistor 19A is less than that of the corner portions of the channel region 3 of the p-type MOS transistor 19B.

Since there is a difference in height between the channel region 3 and the device isolation film 2 of the n-type MOS transistor 19A, the effective channel width is increased by the height as compared to a planar transistor formed in the same layout area. For this reason, the current amount per the same layout area is greater, and the chip area is less in the n-type MOS transistor 19A than in the planar transistor. Furthermore, since the effective channel width is greater in the n-type MOS transistor 19A than in the planar transistor, the fluctuation in threshold voltage is smaller in the n-type MOS transistor 19A. This makes it possible to reduce a minimum operating voltage. The radius of curvature of the corner portions of the channel region 3 in the p-type MOS transistor 19B is greater than that of the n-type MOS transistor 19A, i.e., the corner portions of the channel region 3 in the p-type MOS transistor 19B are rounded. Accordingly, it is possible to prevent the electric field concentration, thereby preventing the degradation of reliability caused by the NBTI stress.

As described above, according to the respective embodiments, it is possible to provide a nonvolatile FPGA that is capable of reducing an increase in costs of a memory embedding process and to reduce the write voltage.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A semiconductor device comprising:
a first protruded semiconductor region extending in a first direction and having a first top surface and first side surfaces that are different from the first top surface and extend along the first direction, a second protruded semiconductor region extending in a second direction and having a second top surface and second side surfaces that are different from the second top surface and extend along the second direction, and a third protruded semiconductor region extending in a third direction and having a third top surface and third side surfaces that are different from the third top surface and extend along the third direction, the first protruded semiconductor region, the second protruded semiconductor region, and the third protruded semiconductor region being formed on a substrate;
a first transistor including:
a first source region and a first drain region that are arranged in the first protruded semiconductor region so as to be spaced apart from each other in the first direction,
a first channel region provided to the first top surface and the first side surfaces of the first protruded semiconductor region between the first source region and the first drain region, the first channel region having a first corner portion in its upper portion in a section that is perpendicular to the first direction, the first corner portion having a first radius of curvature,
a first gate insulating film formed on the first channel region, and
a first gate electrode formed on the first gate insulating film;
a second transistor including:
a second source region and a second drain region that are arranged in the second protruded semiconductor region so as to be spaced apart from each other in the second direction,
a second channel region provided to the second top surface and the second side surfaces of the second protruded semiconductor region between the second source region and the second drain region, the second channel region having a second corner portion in its upper portion in a section that is perpendicular to the second direction, the second corner portion having a second radius of curvature,
a second gate insulating film formed on the second channel region, and
a second gate electrode formed on the second gate insulating film;
a third transistor including:
a third source region and a third drain region that are arranged in the third protruded semiconductor region so as to be spaced apart from each other in the third direction,
a third channel region provided to the third top surface and the third side surfaces of the third protruded semiconductor region between the third source region and the third drain region, the third channel region having a third corner, portion in its upper portion in a section that is perpendicular to the third direction, the third corner portion having a third radius of curvature that is greater than the first radius of curvature and the second radius of curvature,
a third gate insulating film formed on the third channel region, and
a third gate electrode formed on the third gate insulating film;
a first wiring line connected to one of the first source region and the first drain region;
a second wiring line connected to one of the second source region and the second drain region; and
a third wiring line connected to the first gate electrode and the second gate electrode,
the other of the first source region and the first drain region and the other of the second source region and the second drain region being connected to the third gate electrode.

2. The device according to claim 1, wherein:
the first gate electrode covers the first corner portion of the first channel region;
the second gate electrode covers the second corner portion of the second channel region;
the third gate electrode covers the third corner portion of the third channel region;
the first gate insulating film is arranged between the first gate electrode and the first channel region;
the second gate insulating film is arranged between the second gate electrode and the second channel region; and
the third gate insulating film is arranged between the third gate electrode and the third channel region.

3. The device according to claim 1, wherein the radius of curvature in each of the first corner portion and the second corner portion of the first transistor and the second transistor is 9 nm or less, and the radius of curvature of the third corner portion of the third transistor is 10 nm or more.

4. A semiconductor device comprising:
a first protruded semiconductor region extending in a first direction and having a first top surface and first side surfaces that are different from the first top surface and extend along the first direction, a second protruded semiconductor region extending in a second direction and having a second top surface and second side surfaces that are different from the second top surface and extend along the second direction, a third protruded semiconductor region extending in a third direction and having a third top surface and third side surfaces that are different from the third top surface and extend along the third direction, a fourth protruded semiconductor region extending in a fourth direction and having a fourth top surface and fourth side surfaces that are different from the fourth top surface and extend along the fourth direction, and a fifth protruded semiconductor region extending in a fifth direction and having a fifth top surface and fifth side surfaces that are different from the fifth top surface and extend along the fifth direction, the first protruded semiconductor region, the second protruded semiconductor region, the third protruded semiconductor region, the fourth protruded semiconductor region, and the fifth protruded semiconductor region being formed on a substrate;
an SRAM including a first inverter and a second inverter each having a first transistor and a second transistor with a common drain,
a gate of the first transistor and a gate of the second transistor of the first inverter being connected to the common drain of the first transistor and the second transistor of the second inverter,
a gate of the first transistor and a gate of the second transistor of the second inverter being connected to the common drain of the first transistor and the second transistor of the first inverter,
the first transistor of the first inverter including:
a first source region and a first drain region formed in the first protruded semiconductor region so as to be spaced apart from each other in the first direction,
a first channel region provided to the first top surface and the first side surfaces of the first protruded semiconductor region between the first source region and the first drain region, the first channel region having a first corner portion in its upper portion in a section that is perpendicular to the first direction, the first corner portion having a first radius of curvature,
a first gate insulating film formed on the first channel region, and
a first gate electrode formed on the first gate insulating film,
the second transistor of the first inverter including:
a second source region and a second drain region formed in the second protruded semiconductor region so as to be spaced apart from each other in the second direction,
a second channel region provided to the second top surface and the second side surfaces of the second protruded semiconductor region between the second source region and the second drain region, the second channel region having a second corner portion in its upper portion in a section that is perpendicular to the second direction, the second corner portion having a second radius of curvature,
a second gate insulating film formed on the second channel region, and
a second gate electrode formed on the second gate insulating film,
the first transistor of the second inverter including:
a third source region and a third drain region formed in the third protruded semiconductor region so as to be spaced apart from each other in the third direction,
a third channel region provided to the third top surface and the third side surfaces of the third protruded semiconductor region between the third source region and the third drain region, the third channel region having a third corner portion in its upper portion in a section perpendicular to the third direction, the third corner portion having a third radius of curvature,
a third gate insulating film formed on the third channel region, and
a third gate electrode formed on the third gate insulating film,
the second transistor of the second inverter including:
a fourth source region and a fourth drain region formed in the fourth protruded semiconductor region so as to be spaced apart from each other in the fourth direction,
a fourth channel region provided to the fourth top surface and the fourth side surfaces of the fourth protruded semiconductor region between the fourth source region and the fourth drain region, the fourth channel region having a fourth corner portion its upper portion in a section perpendicular to the fourth direction, the fourth corner portion having a fourth radius of curvature,
a fourth gate insulating film formed on the fourth channel region, and
a fourth gate electrode formed on the fourth gate insulating film; and
a third transistor including a fifth source region and a fifth drain region spaced apart from each other in the fifth direction in the fifth protruded semiconductor region,
a fifth channel region provided to the fifth top surface and the fifth side surface in the fifth protruded semiconductor region between the fifth source region and the fifth drain region, the fifth channel region having a fifth corner portion in its upper portion in a section perpendicular to the fifth direction, the fifth corner portion having a fifth radius of curvature, the fifth radius of curvature being greater than any of the first to fourth radius of curvatures,
a fifth gate insulating film formed on the fifth channel region, and
a fifth gate electrode formed on the fifth gate insulating film and receives an output from one of the common drain of the first transistor and the second transistor of the first inverter and the common drain of the first transistor and the second transistor of the second inverter.

5. The device according to claim 4, wherein:
the first gate electrode covers the first corner portion of the first channel region;
the second gate electrode covers the second corner portion of the second channel region;
the third gate electrode covers the third corner portion of the third channel region;
the fourth gate electrode covers the fourth corner portion of the fourth channel region;
the fifth gate electrode covers the fifth corner portion of the fifth channel region;
the first gate insulating film is arranged between the first gate electrode and the first channel region;
the second gate insulating film is arranged between the second gate electrode and the second channel region;
the third gate insulating film is arranged between the third gate electrode and the third channel region;
the fourth gate insulating film is arranged between the fourth gate electrode and the fourth channel region; and
the fifth gate insulating film is arranged between the fifth gate electrode and the fifth channel region.

6. The device according to claim 4, wherein the radius of curvature in each of the first corner portion and the second corner portion of the first transistor and the second transistor is 9 nm or less, and the radius of curvature of the third corner portion of the third transistor is 10 nm or more.

7. A semiconductor device comprising:
a first protruded semiconductor region extending in a first direction and having a first top surface and first side surfaces that are different from the first top surface and extend along the first direction, and a second protruded semiconductor region extending in a second direction and having a second top surface and second side surfaces that are different from the second top surface and extend along the second direction, the first protruded semiconductor region and the second protruded semiconductor region being formed on a substrate;
a first transistor including a first source region and a first drain region that are arranged in the first protruded semiconductor region so as to be spaced apart from each other in the first direction, a first channel region provided to the first top surface and the first side surfaces of the first protruded semiconductor region between the first source region and the first drain region, the first channel region having a first corner portion in its upper portion in a section that is perpendicular to the first direction, the first corner portion having a first radius of curvature, a first gate insulating film formed on the first channel region, and a first gate electrode formed on the first gate insulating film; and
a second transistor including a second source region and a second drain region that are arranged in the second protruded semiconductor region so as to be spaced apart from each other in the second direction, a second channel region provided to the second top surface and the second side surfaces of the second protruded semiconductor region between the second source region and the second drain region, the second channel region having a second corner portion in its upper portion in a section that is perpendicular to the second direction, the second corner portion having a second radius of curvature that is greater than the first radius of curvature, a second gate insulating film formed on the second channel region, and a second gate electrode formed on the second gate insulating film.

8. The device according to claim 7, wherein:
the first gate electrode covers the first corner portion of the first channel region;
the second gate electrode covers the second corner portion of the second channel region;
the first gate insulating film is arranged between the first gate electrode and the first channel region; and,
the second gate insulating film is arranged between the second gate electrode and the second channel region.

9. The device according to claim 7, wherein
the radius of curvature of the first corner portion of the first transistor is 9 nm or less, and the radius of curvature of the second corner portion of the second transistor is 10 nm or more.

10. A method of manufacturing a semiconductor device comprising:
forming a first protruded region and a second protruded region in a semiconductor layer,
the first protruded region extending in a first direction and having a first top surface and first side surfaces that are different from the first top surface and extend in the first direction, a first channel region being provided to the first top surface and the first side surfaces, and
the second protruded region extending in a second direction and having a second top surface and second side surfaces that are different from the second top surface and extend in the second direction, a second channel region being provided to the second top surface and the second side surfaces;
shaping a corner portion in an upper portion of the second channel region in a section perpendicular to the second direction so as to have a radius of curvature that is greater than a radius of curvature of a corner portion in an upper portion of the first channel region in a section perpendicular to the first direction;
forming a first gate insulating film covering the first channel region of the first protruded region, and a second gate insulating film covering the second channel region of the second protruded region; and
forming a first gate electrode covering the first gate insulating film and the corner portion of the first channel region, and a second gate electrode covering the second gate insulating film and the corner portion of the second channel region.

11. The method according to claim 10, wherein the shaping of the corner portion of the second channel region so as to have the radius of curvature greater than the radius of curvature of the corner portion of the first channel region includes:
selectively injecting an impurity to the first channel region to perform amorphization of the first channel region; and
performing hydrogen annealing on the first channel region and the second channel region.
